(19) United States
(12) Patent Application Publication
(10) Pub. No.: US 2026/0100336 A1
(43) Pub. Date: Apr. 9, 2026

(54) APPARATUS AND METHOD OF TREATING SUBSTRATE

(71) Applicant: SEMES CO., LTD., Cheonan-si (KR)

(72) Inventors: Seungjun OH, Hwaseong-si (KR); Jinwoo NAM, Cheongju-si (KR); Janghee LEE, Hwaseong-si (KR); Young Hak PARK, Cheonan-si (KR); Jin Woo CHOI, Suwon-si (KR); Ahn Na SEO, Cheonan-si (KR)

(73) Assignee: SEMES CO., LTD., Cheonan-si (KR)

(21) Appl. No.: 19/406,387

(22) Filed: Dec. 2, 2025

Related U.S. Application Data
(62) Division of application No. 17/695,242, filed on Mar. 15, 2022.

(51) Int. Cl. H01J 37/32; H01J 37/20

(52) U.S. Cl. CPC H01J 37/3244; H01J 37/20; H01J 37/32091; H01J 37/321; H01J 37/32192; H01J 2237/334

(57) ABSTRACT

The present invention provides a method of treating a substrate. The method may include: a first treatment operation in which hydrogen radicals are transferred to a substrate adjusted to have a first temperature to treat the substrate; and a second treatment operation in which the hydrogen radicals are transferred to the substrate adjusted to have a second temperature that is different from the first temperature to treat the substrate.

### CROSS-REFERENCE TO RELATED APPLICATION

This application is a divisional of U.S. application Ser. No. 17/695,242, filed Mar. 15, 2022, the disclosures of each of which are hereby incorporated by reference in their entireties.

### TECHNICAL FIELD

The present invention relates to an apparatus and a method of treating a substrate.

### BACKGROUND ART

As semiconductor devices are highly integrated, a size of an active region has also decreased. As a result, a channel length of an MOS transistor formed in the active region is also reduced. When the channel length of the MOS transistor is reduced, operation performance of the transistor is reduced due to a short channel effect. Accordingly, various studies are being conducted in order to maximize the performance of the devices while reducing the size of the devices formed on the substrate.

A typical example of the device is a fin-FET device having a fin structure. Such a fin-FET device may be formed by etching a substrate, such as a wafer, including silicon (Si). In this case, the roughness of the surface of the substrate generated during the etching process may cause deterioration of the performance of the transistor. Accordingly, damage and roughness of the substrate surface are generally improved through an annealing treatment in which radicals are transferred to the substrate surface. However, when the annealing treatment is performed on the substrate in a state in which the impurities are not properly removed from the substrate, the impurities remaining in the substrate cause performance degradation of the semiconductor device.

### SUMMARY OF THE INVENTION

The present invention has been made in an effort to provide an apparatus and a method of treating a substrate which efficiently treat a substrate.

The present invention has also been made in an effort to provide an apparatus and a method of treating a substrate which effectively perform a surface treatment on a substrate.

The present invention has also been made in an effort to provide an apparatus and a method of treating a substrate which effectively remove impurities remaining on a substrate.

The present invention has also been made in an effort to provide an apparatus and a method of treating a substrate which effectively improve surface damage and roughness of a substrate.

The effect of the present invention is not limited to the foregoing effects, and non-mentioned effects will be clearly understood by those skilled in the art from the present specification and the accompanying drawings.

An exemplary embodiment of the present invention provides an apparatus for treating a substrate, the apparatus including: a process chamber having a treatment space; a substrate support unit configured to support a substrate in the treatment space and including a heater for adjusting a temperature of the substrate; a gas supply unit configured to supply process gas to the treatment space; a gas exciting unit configured to excite the process gas and generate radicals; and a control unit, in which the control unit controls the gas supply unit and the gas exciting unit so as to generate the radicals by supplying the process gas to the treatment space, and controls the substrate support unit so as to adjust the temperature of the substrate to a first temperature and then adjust the temperature of the substrate to a second temperature that is different from the first temperature while the radicals are transferred to the substrate.

According to the exemplary embodiment, the control unit may control the substrate support unit so that the second temperature is higher than the first temperature.

According to the exemplary embodiment, the control unit may control the substrate support unit so that the first temperature is between 50° C. to 300° C.

According to the exemplary embodiment, the control unit may control the substrate support unit so that the second temperature is between 400° C. to 700° C.

According to the exemplary embodiment, in the process chamber, at least one exhaust hole connected with an exhaust line for exhausting the treatment space may be formed, and the control unit may control a decompressing member connected with the exhaust line so that a pressure of the treatment space is between 10 mTorr and 4 Torr.

According to the exemplary embodiment, impurities containing germanium (Ge) may be attached to the substrate treated by the radicals, and the substrate may be made of a material containing silicon (Si).

According to the exemplary embodiment, the process gas supplied by the gas supply unit may include at least one selected from hydrogen and inert gas.

According to the exemplary embodiment, the gas exciting unit may include: a microwave power supply; and a microwave antenna configured to receive power applied by the microwave power supply and apply microwaves to the treatment space.

Another exemplary embodiment of the present invention provides a substrate treating apparatus treating a surface of a substrate to which germanium (Ge) is attached, the substrate treating apparatus including: a process chamber having a treatment space; a substrate support unit configured to support a substrate in the treatment space and including a temperature adjusting member for adjusting a temperature of the substrate; a gas supply unit configured to supply process gas containing hydrogen to the treatment space; a gas exciting unit configured to excite the process gas and generate hydrogen radicals; and a control unit, in which the control unit controls the gas supply unit and the gas exciting unit so as to perform a first treatment operation in which the hydrogen radicals are transferred to the substrate to remove the germanium, and a second treatment operation in which the hydrogen radicals are transferred to the substrate to improve surface roughness of the substrate.

According to the exemplary embodiment, the control unit may control the substrate support unit so that the temperature of the substrate becomes a first temperature in the first treatment operation, and the temperature of the substrate becomes a second temperature that is different from the first temperature in the second treatment operation. According to the exemplary embodiment, the control unit may control the substrate support unit so that the second temperature is higher than the first temperature. According to the exemplary embodiment, the control unit may control the substrate support unit so that the first temperature is between 50° C. to 300° C., and the second temperature is between 400° C. to 700° C.

According to the exemplary embodiment, the substrate may be made of a material containing silicon (Si).

Another exemplary embodiment of the present invention provides a method of treating a substrate, the method including: a first treatment operation in which hydrogen radicals are transferred to a substrate of which a temperature is adjusted to a first temperature to treat the substrate; and a second treatment operation in which the hydrogen radicals are transferred to the substrate of which the temperature is adjusted to a second temperature that is different from the first temperature to treat the substrate.

According to the exemplary embodiment, the second temperature may be higher than the first temperature.

According to the exemplary embodiment, the first temperature may be 50° C. or higher and 300° C. or lower.

According to the exemplary embodiment, the second temperature may be 400° C. or higher and 700° C. or lower.

According to the exemplary embodiment, a pressure within a vacuum chamber providing a space in which the substrate is treated may be 10 mTorr or more and 4 Torr or less.

According to the exemplary embodiment, in the first treatment operation, impurities containing germanium (Ge) attached onto the substrate may be removed, and the second treatment operation may be performed after the first treatment operation, and in the second treatment operation, surface roughness of the substrate that is made of a material containing silicon (Si) may be improved.

According to the exemplary embodiment, plasma including the hydrogen radicals may be any one of direct plasma and remote plasma.

According to the exemplary embodiment of the present invention, it is possible to efficiently process a substrate.

Further, according to the exemplary embodiment of the present invention, it is possible to minimize the transfer of the impurities to the substrate by adjusting an electric field generated in a peripheral region of the substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram illustrating a substrate treating apparatus according to an exemplary embodiment of the present invention.

FIG. 2 is a flowchart illustrating a substrate treating method according to an exemplary embodiment of the present invention.

FIG. 3 is a diagram illustrating the substrate treating apparatus performing a first treatment operation of FIG. 2.

FIG. 4 is a diagram illustrating the substrate after a second treatment operation of FIG. 2 is performed.

FIG. 5 is a diagram illustrating the substrate treating apparatus performing the second treatment operation of FIG. 2.

FIG. 6 is a diagram illustrating the substrate after the second treatment operation of FIG. 2 is performed.

FIG. 7 is a graph representing the efficiency of removing impurities attached to the substrate by radicals according to a temperature of a substrate.

FIG. 8 is a diagram illustrating the substrate on which the first treatment operation is being performed in the case where a fin is formed on the substrate.

FIG. 9 is a diagram illustrating the substrate on which the first treatment operation has been performed in the case where the fin is formed on the substrate.

FIG. 10 is a diagram illustrating the substrate on which the second treatment operation is being performed in the case where the fin is formed on the substrate.

FIG. 11 is a diagram illustrating the substrate on which the second treatment operation has been performed in the case where the fin is formed on the substrate.

FIG. 12 is a diagram illustrating the substrate on which the first treatment operation is being performed in the case where a sheet structure is formed on the substrate.

FIG. 13 is a diagram illustrating the substrate on which the first treatment operation has been performed in the case where a sheet structure is formed on the substrate.

FIG. 14 is a diagram illustrating the substrate on which the second treatment operation is being performed in the case where a sheet structure is formed on the substrate.

FIG. 15 is a diagram illustrating the substrate on which the second treatment operation has been performed in the case where a sheet structure is formed on the substrate.

### DETAILED DESCRIPTION

Hereinafter, an exemplary embodiment of the present invention will be described more fully hereinafter with reference to the accompanying drawings, in which exemplary embodiments of the invention are shown. However, the present invention can be variously implemented and is not limited to the following embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “comprise” and variations such as “comprises” or “comprising” will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between” and “just between” or “adjacent to ˜”, and “directly adjacent to ˜”should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

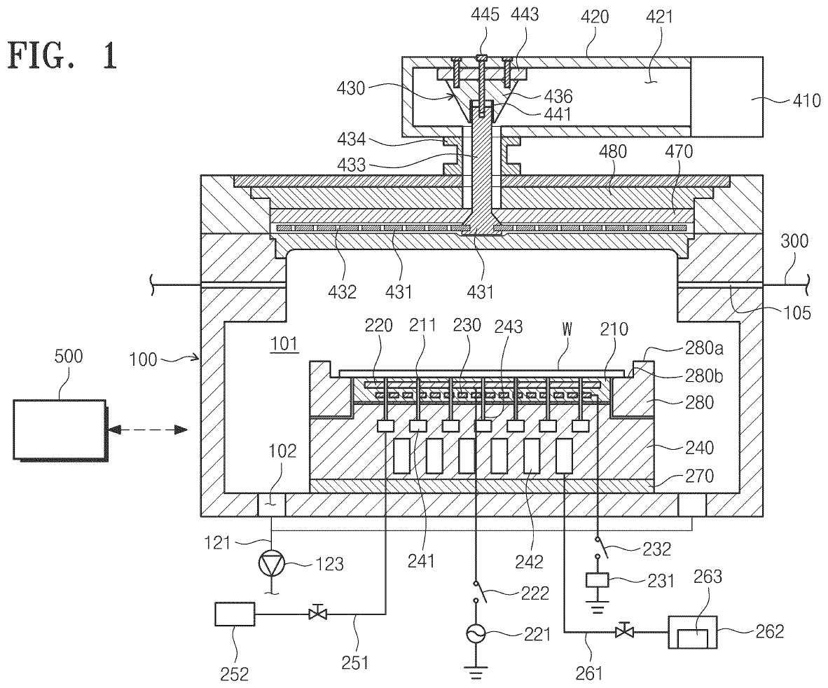

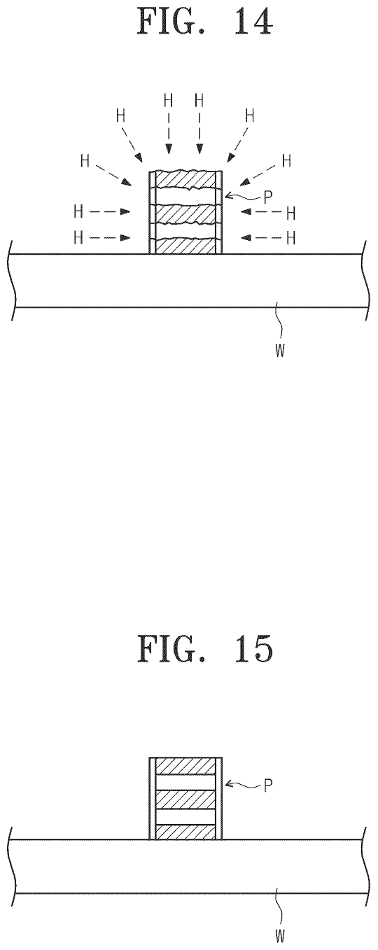

Hereinafter, an exemplary embodiment of the present invention will be described in detail with reference to FIGS. 1 to 15.

FIG. 1 is a diagram illustrating a substrate treating apparatus according to an exemplary embodiment of the present invention.

Referring to FIG. 1, a substrate treating apparatus performs a plasma process processing on a substrate W. The substrate treating apparatus includes a process chamber 100, a substrate support unit 200, a gas supply unit 300, a microwave applying unit 400, and a control unit 500.

The process chamber 100 may have a treatment space 101. The treatment space 101 may be a space in which the substrate W is treated. An opening (not illustrated) may be formed in one lateral wall of the process chamber 100. The opening is provided as a path through which the substrate W is capable of entering to the process chamber 100. The opening is opened/closed by a door (not illustrated). An exhaust hole 102 is formed in a bottom surface of the process chamber 100. The exhaust hole 102 is connected with an exhaust line 121. The exhaust line 121 may be connected with a decompression member 123. The decompression member 123 may be a pump. Reaction by-products generated during the process and gas remaining inside the process chamber 100 may be discharged to the outside through the exhaust line 121.

Further, the pressure of the treatment space 101 may be maintained at a set pressure by the pressure reduction provided by the decompression member 123 through the exhaust line 121. The pressure of the treatment space 101 may be maintained at a pressure close to vacuum. That is, the process chamber 100 may be a vacuum chamber in which the pressure of the treatment space 101 is maintained at a pressure close to vacuum while the substrate W is processed. For example, the control unit 500, which is to be described below, may control the decompression member so that the pressure of the treatment space 101 is a pressure between 10 mTorr to 4 Torr (for example, 10 mTorr or more and 4 Torr or less).

A substrate support unit 200 is located inside the process chamber 100. The substrate support unit 200 supports the substrate W. The substrate support unit 200 includes an electrostatic chuck for adsorbing the substrate W by using electrostatic force.

The electrostatic chuck 200 includes a dielectric plate 210, a lower electrode 220, a heater 230, a support plate 240, an insulating plate 270, and a focus ring 280.

The dielectric plate 210 is positioned at an upper portion of the electrostatic chuck 200. The dielectric plate 210 is provided as a disk-shaped dielectric substance. The substrate W is placed on an upper surface of the dielectric plate 210. The upper surface of the dielectric plate 210 has a smaller radius than that of the substrate W. Therefore, an edge region of the substrate W is positioned outside the dielectric plate 210. A first supply path 211 is formed in the dielectric plate 210. The first supply path 211 is provided from an upper surface to a bottom surface of the dielectric plate 210. A plurality of first supply paths 211 is formed while being spaced apart from each other, and is provided as a passage through which a heat transfer medium is supplied to the bottom surface of the substrate W.

The lower electrode 220 and the heater 230 are embedded in the dielectric plate 210. The lower electrode 220 is positioned above the heater 230. The lower electrode 220 is electrically connected with a lower power supply 221. The lower power supply 221 includes a direct-current power source. A lower power switch 222 is installed between the lower electrode 220 and the lower power supply 221. The lower electrode 220 may be electrically connected with the lower power supply 221 by on/off of the lower power switch 222. When the lower power switch 222 is turned on, a DC current is applied to the lower electrode 220. Electric force acts between the lower electrode 220 and the substrate W by the current applied to the lower electrode 220, and the substrate W is adsorbed to the dielectric plate 210 by the electric force.

The heater 230 may be a temperature adjusting member adjusting a temperature of the substrate W to a set temperature. Further, the substrate W is maintained at a predetermined temperature by heat generated in the heater 230. The heater 230 includes a spiral-shaped coil. The heaters 230 may be embedded in the dielectric plate 210 at a constant interval. The heater 230 may be heated by receiving power from a heater power supply 231. Further, a heater power switch 232 may be installed between the heater 230 and the heater power supply 231. The heater 230 may be electrically connected with the heater power supply 231 by on/off of the heater power switch 232. Further, a temperature of the heater 230 may be changed according to a size of the power applied to the heater 230 by the heater power supply 231. For example, the temperature of the heater 230 may also be increased in proportion to the size of the power applied to the heater 230. Further, the heater 230 may be connected with a heater sensor (not illustrated) which senses a temperature of the heater 230. The heater sensor may detect a temperature of the heater 230 in real time, and transfer the detected real-time temperature of the heater 230 to the control unit 500. The control unit 500 may vary the size of the power transferred to the heater 230 based on the temperature of the heater 230 detected by the heater sensor.

The support plate 240 is located under the dielectric plate 210. The bottom surface of the dielectric plate 210 and an upper surface of the support plate 240 may be bonded by an adhesive 236. The support plate 240 may be made of aluminum. The upper surface of the support plate 240 may be stepped so that a center region is higher than an edge region. The center region of the upper surface of the support plate 240 has an area corresponding to the bottom surface of the dielectric plate 210, and is bonded to the bottom surface of the dielectric plate 210. A first circulation flow path 241, a second circulation flow path 242, and a second supply flow path 243 are formed in the support plate 240.

The first circulation flow path 241 is provided as a passage in which a heat transfer medium is circulated. The first circulation flow path 241 may be formed in a spiral shape inside the support plate 240. Otherwise, the first circulation flow paths 241 may be arranged such that the ring-shaped flow paths having different radii have the same center. Each of the first circulation flow paths 241 may communicate with each other. The first circulation flow paths 241 are formed at the same height.

The second circulation flow path 242 is provided as a passage in which a cooling fluid is circulated. The second circulation flow path 242 may be formed in a spiral shape inside the support plate 240. Otherwise, the second circulation flow paths 242 may be arranged such that the ring-shaped flow paths having different radii have the same center. Each of the second circulation flow paths 242 may communicate with each other. The second circulation flow path 242 may have a larger cross-sectional area than that of the first circulation flow path 241. The second circulation flow paths 242 are formed at the same height. The second circulation flow paths 242 may be positioned under the first circulation flow paths 241.

The second supply flow path 243 is extended from the first circulation flow path 241 in an upper direction and is provided to an upper surface of the support plate 240. The second supply flow paths 243 are provided in a number corresponding to the number of first supply flow paths 211, and connect the first circulation flow paths 241 and the first supply flow paths 211.

The first circulation flow path 241 is connected with a heat transfer medium storage unit 252 through a heat transfer medium supply line 251. A heat transfer medium is stored in the heat transfer medium storage unit 252. The heat transfer medium includes inert gas. According to the exemplary embodiment, the heat transfer medium includes helium (He) gas. The helium gas is supplied to the first circulation flow path 241 through the supply line 251, and is supplied to the bottom surface of the substrate W by sequentially passing through the second supply flow path 243 and the first supply flow path 211. The helium gas serves as a medium by which heat transferred from plasma to the substrate W is transferred to the electrostatic chuck 200. Ion particles contained in the plasma area attracted to the electric force formed in the electrostatic chuck 200 and move to the electrostatic chuck 200, and collide with the substrate W in the process of moving and perform an etching process. In the process in which the ion particles collide with the substrate W, heat is generated in the substrate W. Heat generated in the substrate W is transferred to the electrostatic chuck 200 through helium gas supplied between the bottom surface of the substrate W and the upper surface of the dielectric plate 210. Therefore, the substrate W may be maintained at a set temperature.

The second circulation flow path 242 is connected with a cooling fluid storage unit 262 through a cooling fluid supply line 261. A cooling fluid is stored in the cooling fluid storage unit 262. A cooler 263 may be provided inside the cooling fluid storage unit 262. The cooler 263 cools the cooling fluid to a predetermined temperature. Contrary to this, the cooler 263 may be installed on the cooling fluid supply line 261. The cooling fluid supplied to the second circulation flow path 242 through the cooling fluid supply line 261 cools the support plate 240 while circulating along the second circulation flow path 242. The cooling of the support plate 240 cools the dielectric plate 210 and the substrate W together to maintain the substrate W at a predetermined temperature.

The insulating plate 270 is provided under the support plate 240. The insulating plate 270 is provided in a size corresponding to the size of the support plate 240. The insulating plate 270 is positioned between the support plate 240 and the bottom surface of the chamber 100. The insulating plate 270 is made of an insulating material, and electrically insulates the support plate 240 and the chamber 100.

The focus ring 280 is disposed in the edge region of the electrostatic chuck 200. The focus ring 280 has a ring shape, and is disposed along a circumference of the dielectric plate 210. An upper surface of the focus ring 280 may be stepped so that an outer portion 280a is higher than an inner portion 280b. The inner portion 280b of the upper surface of the focus ring 280 is positioned at the same height as that of the upper surface of the dielectric plate 210. The inner portion 280b of the upper surface of the focus ring 280 supports the edge region of the substrate W positioned at the external side of the dielectric plate 210. The outer portion 280a of the focus ring 280 is provided so as to surround the edge region of the substrate W. The focus ring 280 expands the electric field formation region so that the substrate W is positioned at the center of the region where the plasma is formed. Therefore, plasma is uniformly formed throughout the entire region of the substrate W and each region of the substrate W may be uniformly etched.

The gas supply unit 300 supplies process gas to the treatment space 101 of the process chamber 100. The gas supply unit 300 may supply process gas into the process chamber 100 through a gas supply hole 105 formed in a lateral wall of the process chamber 100. The process gas supplied by the gas supply unit 300 to the treatment space 101 may contain at least one gas selected from hydrogen and inert gas. The inert gas may include helium (He), neon (Ne), argon (Ar), krypton (Kr), xenon (Xe), radon (Rn), and the like.

The microwave application unit 400 may be a gas excitation unit that applies microwaves to the treatment space 101 of the process chamber 100 to excite the process gas. For example, the microwave application unit 400 may generate plasma by exciting the process gas. The plasma excited from the process may contain hydrogen radicals. Hydrogen radicals may be transferred to the substrate W to remove impurities attached onto the substrate W or improve roughness of the surface of the substrate W.

The microwave application unit 400 includes a microwave power supply 410, a waveguide 420, a microwave antenna 430, a dielectric block 450, an electrode plate 460, a dielectric plate 470, and a cooling plate 480.

The microwave power supply 410 generates microwaves. The waveguide 420 is connected to the microwave power supply 410, and provides a path through which the microwave generated in the microwave power supply 410 is transferred.

The microwave antenna 430 is positioned inside the front end of the waveguide 420. The microwave antenna 430 applies the microwave transferred through the waveguide 420 into the process chamber 100. For example, the microwave antenna 430 may receive power applied by the microwave power supply 410 and apply the microwave to the treatment space 101.

The microwave antenna 430 includes an antenna 431, an antenna rod 433, an external conductor 434, a microwave adaptor 436, a connector 441, a cooling plate 443, and an antenna height adjusting unit 445.

The antenna 431 is provided as a thin disk, and a plurality of slot holes 432 is formed. The slot holes 432 provide passages through which the microwaves pass. The slot holes 432 may be provided in various shapes. The slot holes 432 may be provided in a shape, such as ‘×’, ‘+’, and ‘−’. The slot holes 432 may be combined with each other and arranged in a plurality of ring shapes. The rings have the same center, and different radii.

The antenna rod 433 is provided as a cylindrical rod. A longitudinal direction of the antenna rod 433 is arranged in a vertical direction. The antenna rod 433 is positioned in an upper portion of the antenna 431, and a lower end of the antenna rod 433 is inserted and fixed to the center of the antenna 431. The antenna rod 433 propagates the microwaves to the antenna 431.

The external conductor 434 is positioned below the front end of the waveguide 420. A space connected with the internal space of the waveguide 420 is formed in the vertical direction inside the external conductor 434. A partial region of the antenna rod 433 is positioned inside the external conductor 434.

A microwave adaptor 436 is located inside the front end of the wave guide 420. The microwave adaptor 436 has a cone shape in which an upper end has a larger radius than that of the lower end. At the lower end of the microwave adaptor 436, a receiving space 437 with an open bottom is formed. An entrance 438 of the receiving space 437 is provided with a relatively smaller radius than that of the inner region.

A connector 441 is positioned in the receiving space 437. The connector 441 is provided in a ring shape. An outer surface of the connector 441 has a radius corresponding to that of an inner surface of the receiving space 437. The outer surface of the connector 441 is in contact with the inner surface of the receiving space 437 and is fixedly located. The connector 441 may be formed of a conductive material. An upper end of the antenna rod 433 is positioned inside the receiving space 437, and is fitted to an inner region of the connector 441. The upper end of the antenna rod 433 is forcibly fitted to the connector 441, and is electrically connected with the microwave adaptor 436 through the connector 441.

The cooling plate 443 is coupled to the upper end of the microwave adaptor 436. The cooling plate 443 may be provided as a plate having a larger radius than that of the upper end of the microwave adaptor 436. The cooling late 443 may be provided with a material having superior thermal conductivity than the microwave adaptor 436. The cooling plate 443 may be formed of a copper (Cu) or aluminum (Al) material. The cooling plate 443 facilitates cooling of the microwave adaptor 436 to prevent thermal deformation of the microwave adaptor 436.

The antenna height adjusting unit 445 connects the microwave adaptor 436 and the antenna rod 433. Further, the antenna height adjusting unit 445 moves the antenna rod 433 so that a relative height of the antenna 431 to the microwave adaptor 436 is changed. The antenna height adjusting unit 445 includes a bolt. The bolt 445 is inserted to the microwave adaptor 436 in the vertical direction from the top to the bottom of the microwave adaptor 436, and a lower end is located in the receiving space 437. The bolt 445 is inserted into the center region of the microwave adaptor 436. The lower end of the bolt 445 is inserted into the upper end of the antenna rod 433. In the upper end of the antenna rod 433, a screw groove into which the lower end of the bolt 445 is inserted and fastened is formed to a predetermined length. The antenna rod 433 moves in the vertical direction along the rotation of the bolt 445. For example, when the bolt 445 rotates in a clockwise direction, the antenna rod 433 may move up, and when the bolt 445 rotates in a counterclockwise direction, the antenna rod 433 may move down. Together with the movement of the antenna rod 433, the antenna 431 may move in the vertical direction.

The dielectric plate 470 is located above the antenna 431. The dielectric plate 470 is provided with a dielectric, such as alumina and quartz. The microwave propagated from the microwave antenna 430 in the vertical direction is propagated in the radius direction of the dielectric plate 470. The microwave propagated to the dielectric plate 470 has a compressed wavelength and is resonant. The resonant microwave is transmitted to the slot holes 432 of the antenna 431.

The cooling plate 480 is provided above the dielectric plate 470. The cooling plate 480 cools the dielectric plate 470. The cooling plate 480 may be made of an aluminum material. The cooling plate 480 may cool the dielectric plate 470 by flowing a cooling fluid through a cooling flow path (not illustrated) formed therein. The cooling method includes a water cooling type and an air cooling type.

The dielectric block 450 is provided under the antenna 431. The dielectric block 450 is provided with a dielectric, such as alumina and quartz. The microwaves passing through the slot holes 432 of the antenna 431 are radiated into the process chamber 100 through the dielectric block 450. By the electric field of the radiated microwave, the process gas supplied into the process chamber 100 is excited into a plasma state. The upper surface of the dielectric block 450 may be spaced apart from the bottom surface of the antenna 431 at a predetermined interval.

In the structure of the microwave antenna 430, the antenna height adjusting unit 445 limits a horizontal movement of the antenna rod 433. In the process of propagating the microwave, heat is generated in the microwave adaptor 436 and the connector 441. The generated heat deforms the microwave adaptor 436 and the connector 441, and the degree of fitting of the antenna rod 433 to the connector 441 is loosened by the deformation, so that the antenna rod 433 may move in the horizontal direction. When the antenna rod 433 moves in the horizontal direction, an interval between the microwave adaptor 436 and the antenna rod 433 may be different depending on a region. The difference in the interval makes the microwaves propagated to the antenna rod 433 non-uniform. Further, when the antenna rod 322 is in contact with the microwave adaptor 436 due to the movement of the antenna rod 433, an arc may be caused. The antenna height adjusting unit 445 limits the horizontal movement of the antenna rod 433 with respect to the microwave adaptor 436, so that the foregoing problem caused due to the thermal deformation of the microwave adaptor 436 and the connector 441 is prevented.

Further, the antenna height adjusting unit 445 may move the antenna rod 433 in the vertical direction so that a relative height of the antenna 431 to the microwave adaptor 436 is changed. When the degree of fitting of the antenna rod 433 is loosened by the thermal deformation of the microwave adaptor 436 and the connector 441, the antenna 431 may be in contact with the dielectric block 450 while the antenna rod 433 droops down. The contact between the antenna 431 and the dielectric block 450 may also occur by a thermal shape of the antenna 431. The contact between the antenna 431 and the dielectric block 450 causes loss of the propagated microwaves. As described above, when the contact between the antenna 431 and the dielectric block 450 occurs, the antenna height adjusting unit 445 may move the antenna rod 433 in an upper direction so that the antenna 431 and the dielectric block 450 maintain a predetermined interval. Further, the antenna height adjusting unit 445 may maintain an appropriate interval between the antenna 431 and the dielectric block 450 by moving the antenna rod 433 in the vertical direction.

The control unit 500 may control the substrate treating apparatus. The control unit 500 may control at least one of the substrate support unit 200, the gas supply unit 300, and the microwave apply unit 400 of the substrate treating apparatus so that the substrate treating apparatus performs a substrate treating method to be described below. Further, the control unit 500 may include a process controller formed of a microprocessor (computer) executing the control of the substrate treating apparatus, a user interface formed of a keyboard through which an operator performs a command input manipulation and the like for managing the substrate treating apparatus, a display for visualizing and displaying an operation situation of the substrate treating apparatus, or the like, and a storage unit in which a control program for executing the processing executed in the substrate treating apparatus under the control of the process controller or various data and a program, that is, a processing recipe, for executing processing on each configuration according to processing conditions are stored. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

Further, the control unit 500 may maintain the temperature of the substrate W at a set temperature by adjusting the size of power transferred to the heater 230 by the heater power supply 231. For example, the control unit 500 may recognize a temperature of the heater 230 detected by the heater sensor in real time. Further, parameters for changing the temperature of the substrate W according to the temperature of the heater 230, which are experimental data performed in advance, may be input to the control unit 500.

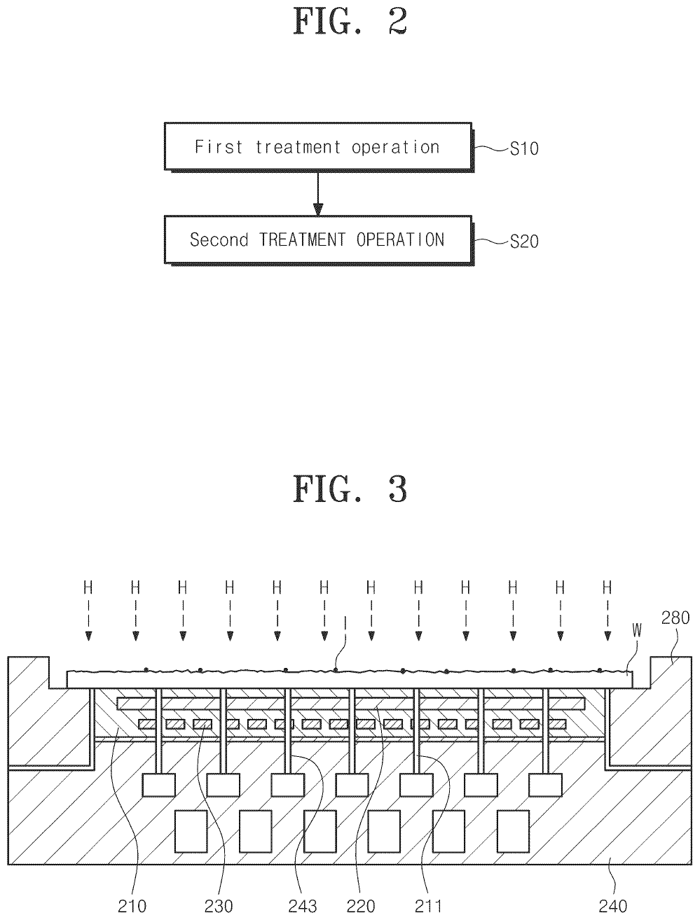

FIG. 2 is a flowchart illustrating a substrate treating method according to an exemplary embodiment of the present invention. Referring to FIG. 2, the substrate treating method according to the exemplary embodiment of the present invention may include a first treatment operation S10 and a second treatment operation S20. The first treatment operation S10 and the second treatment operation S20 may be sequentially performed. For example, after the first treatment operation S10 is performed, the second treatment operation S20 may be performed. Further, the substrate W treated through the first treatment operation S10 and the second treatment operation S20 may be made of a material including silicon (Si).

FIG. 3 is a diagram illustrating the substrate treating apparatus performing a first treatment operation of FIG. 2. Referring to FIG. 3, the first treatment operation S10 may be an impurity removing operation in which impurities I remaining on the substrate W are removed. The impurities I removed in the first treatment operation S10 may be a by-product generated while etching the substrate W, or a residual film formed on the substrate W that has not been removed through the etching process. For example, the impurities I attached onto the substrate W may be a compound including germanium (Ge). For example, the impurities I may include SiGe or GeO.

In the first treatment operation S10, the control unit 500 may maintain a temperature of the substrate W at a first temperature by controlling the substrate support unit 200. The first temperature may be a temperature between 50° C. to 300° C. (for example, 50° C. or higher and 300° C. or lower). Further, the impurities I remaining on the substrate W may be removed by maintaining the temperature of the substrate W at the first temperature while hydrogen radicals excited from process gas are transferred to the surface of the substrate W.

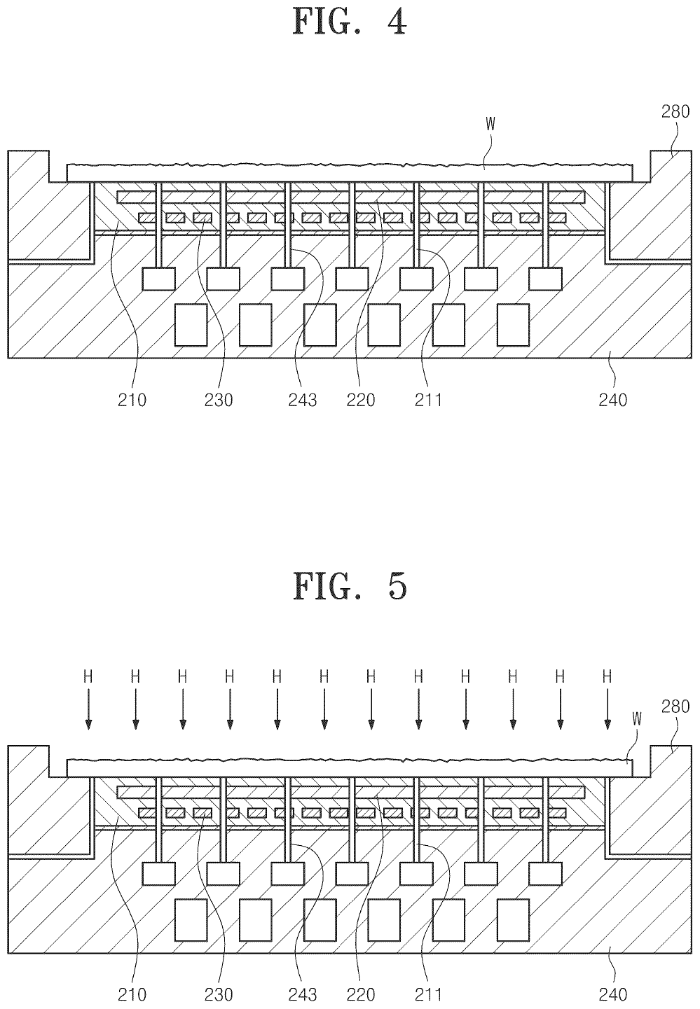

When the performance of the first treatment operation S10 is completed, the impurities I attached onto the substrate W may be removed from the substrate W as illustrated in FIG. 4.

FIG. 5 is a diagram illustrating the substrate treating apparatus performing the second treatment operation of FIG. 2. Referring to FIG. 5, the second treatment operation S20 may be a surface roughness improvement operation of reducing surface roughness of the substrate W. The substrate W may be made of a material including silicon (Si) as described above.

In the second treatment operation S20, the control unit 500 may maintain the temperature of the substrate W at a second temperature that is different from the first temperature by controlling the substrate support unit 200. The second temperature may be higher than the first temperature. The second temperature may be a temperature between 400° C. to 700° C. (for example, 400° C. or higher and 700° C. or lower). Further, the surface roughness of the substrate W may be improved by changing the temperature of the substrate W from the first temperature to the second temperature and maintaining the temperature of the substrate W at the second temperature while hydrogen radicals excited from process gas are transferred to the surface of the substrate W.

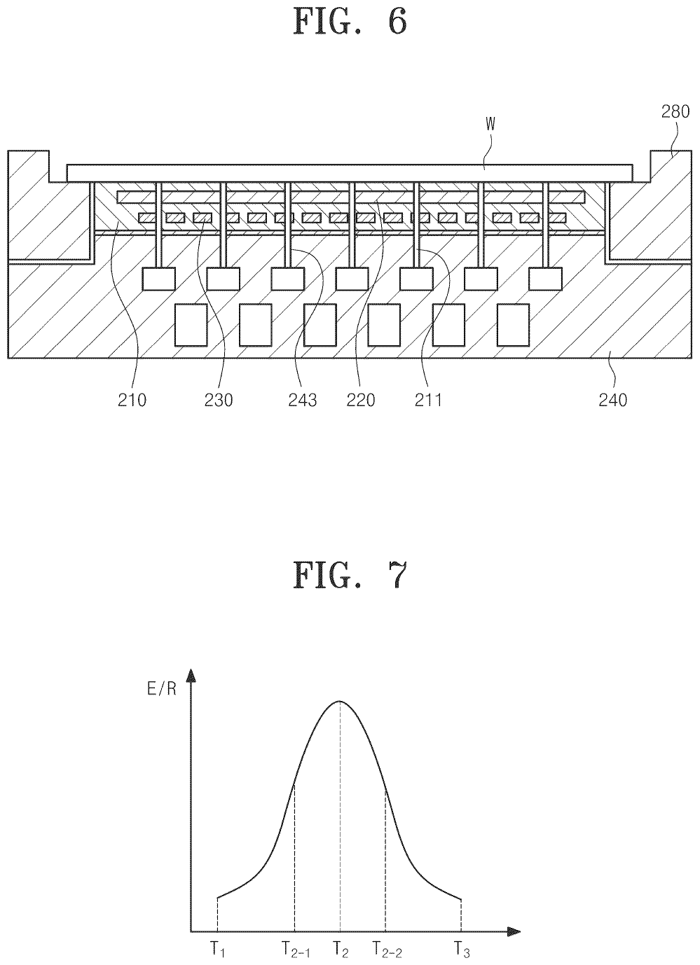

When the performance of the second treatment operation S20 is completed, the impurities attached onto the substrate W may be removed as illustrated in FIG. 6. Further, the second treatment operation S20 is performed after the first treatment operation S10 is performed. That is, the second treatment operation S20 is performed in the state where the impurities are removed from the substrate W, so that it is possible to minimize the problem of performance degradation of the semiconductor device.

FIG. 7 is a graph representing the efficiency of removing impurities attached to the substrate by radicals according to a temperature of a substrate. In particular, FIG. 7 is the graph showing impurity (I) removal efficiency (etch rate) by hydrogen radicals according to the change in the temperature of the substrate W when the impurities I attached to the substrate W are the compound containing germanium (Ge).

Referring to FIG. 7, the etch rate of the compound containing germanium (Ge) by the hydrogen radicals is high between a first temperature T₁ and a third temperature T₃, and is highest, particularly, at a second temperature T₂. The first temperature T₁ may be about 50° C., and the third temperature may be about 300° C. Further, the second temperature T₂ may be about 180° C. That is, in the case where the impurity I attached onto the substrate W is the compound containing germanium (Ge), when the temperature of the substrate W is adjusted to about 180° C., the etch rate of the impurities I by hydrogen radicals is highest. Therefore, in the first treatment operation S10, it may be preferable that the temperature of the substrate W is maintained at about a second-1 temperature (T₂₋₁, for example, about 160° C.) to a second-two temperature (T₂₋₂, for example, about 200° C.).

That is, in the first treatment operation S10 and the second treatment operation S20 of the present invention, the temperature of the substrate W is differently maintained at the first temperature and the second temperature, respectively. The first temperature is 50° C. to 300° C., and the second temperature is 400° C. to 700° C. as described above.

The first temperature and the second temperature may be classified according to a predominant temperature region in which silicon (Si) and germanium (Ge) become volatile species (SiH₄, GeH₄). When silicon (Si) and germanium (Ge) react with hydrogen radicals to become volatile species, silicon (Si) and germanium (Ge) may be removed from the surface of the substrate W.

The temperature region in which germanium (Ge) is removed by hydrogen radicals may be 50° C. to 300° C. In particular, the temperature at which the germanium (Ge) etch rate is highest by hydrogen radicals is about 180° C. Now, in the first treatment operation S10, the impurities I including germanium (Ge) may be effectively removed from the substrate W.

Further, in the first treatment operation S10, it is preferable that the temperature of the substrate W does not exceed 300° C. In the case of the silicon (Si) forming the substrate W, the temperature region in which the impurities are removed by hydrogen radicals is about 300° C. to 400° C., and when the temperature of the substrate W exceeds 300° C. in the first treatment operation S10, because not only the impurity I containing germanium (Ge) is removed, but also the substrate W itself may be damaged, so that the temperature of the substrate W exceeding 300° C. is not appropriate.

Further, in the second treatment operation S20, it is preferable that the temperature of the substrate W is maintained at about 400° C. to 700° C. In the case of silicon (Si), when the temperature of the substrate W is maintained at about 400° C. to 700° C. at a hydrogen radical atmosphere, silicon (Si) improves surface roughness of the substrate W by surface diffusion.

Further, in the second treatment operation S20, it is preferable that the temperature of the substrate W exceed 400° C. In the case of the silicon (Si) forming the substrate W, the temperature region in which the impurities are removed by hydrogen radicals is about 300° C. to 400° C., and when the temperature of the substrate W falls below 400° C. in the second treatment operation S20, surface roughness of the substrate W is not improved, but damage may be caused to the substrate W itself, so that the temperature of the substrate W below 300° C. is not appropriate.

That is, in the method of treating the substrate according to the exemplary embodiment of the present invention, after the first treatment operation S10 is performed to remove impurities I from the substrate W, the second treatment operation S20 is performed to improve surface roughness of the substrate W, so that it is possible to more effectively improve surface roughness of the substrate W. Further, it is possible to more efficiently and effectively treat the substrate W by adjusting the temperature of the substrate W to the temperature at which the impurities I are easily removed in the first treatment operation S10, and adjusting the temperature of the substrate W to the temperature at which surface roughness of the substrate W is easily improved in the second treatment operation S20.

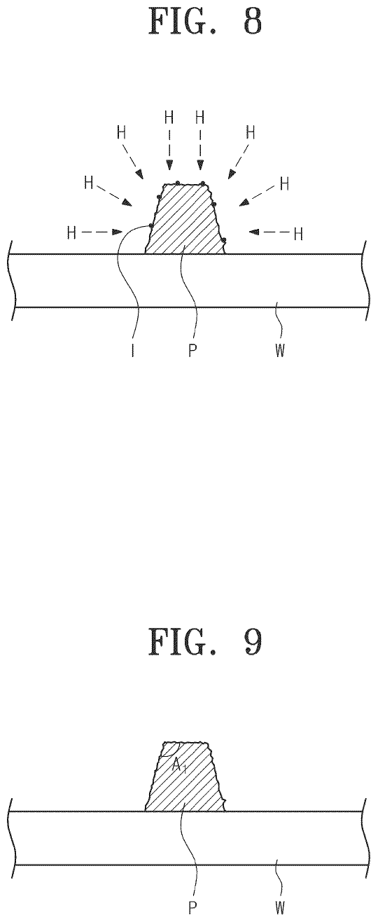

Hereinafter, application examples of the first treatment operation S10 and the second treatment operation S20 of the present invention will be described. As illustrated in FIG. 8, a pattern P having a pin structure may be formed on the substrate W through patterning and etching processes. An impurity I containing germanium (Ge) may be attached to the pattern P.

When the first treatment operation S10 is performed, hydrogen radicals are transferred to the substrate W, and the temperature of the substrate W may be maintained at a first temperature (see FIG. 8). When the performance of the first treatment operation S10 is completed, the impurities I attached to the pattern P may be removed (see FIG. 9). In this case, an angle formed between an upper surface and a lateral surface of the pattern P may be a first angle A₁.

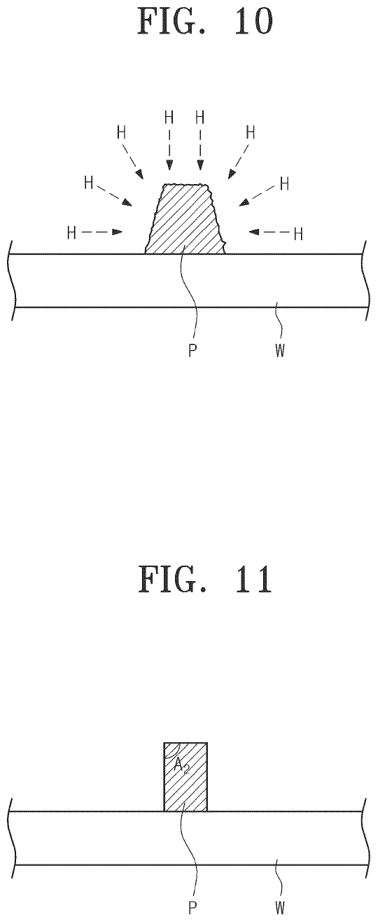

When the second treatment operation S20 is performed, hydrogen radicals are transferred to the substrate W, and the temperature of the substrate W may be maintained at a second temperature (see FIG. 10). When the performance of the second treatment operation S20 is completed, surface roughness of the substrate W may be improved (see FIG. 11). In this case, an angle formed between an upper surface and a lateral surface of the pattern P may be a second angle A₂ that is close to a right angle. That is, the form of the pattern P formed on the substrate W may also be improved through the second treatment operation S20.

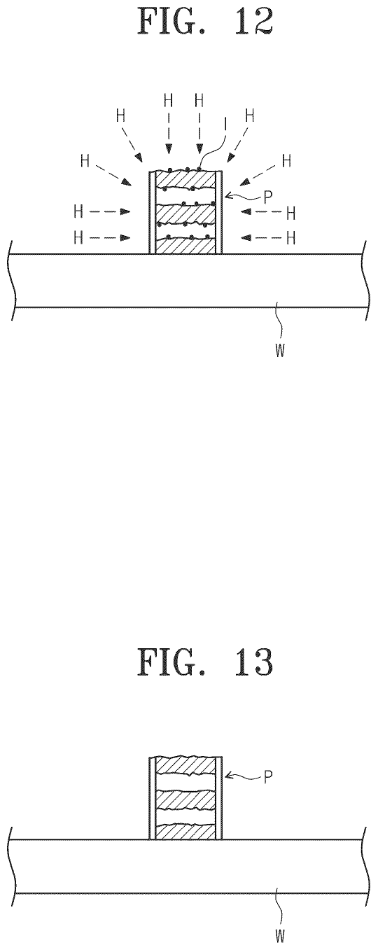

Further, the hydrogen radical does not have directionality. Therefore, even in the case where the pattern P in a sheet structure having a space separated from the substrate W is formed on the substrate W as illustrated in FIG. 12, the first treatment operation S10 and the second treatment operation S20 may also be identically or similarly applied.

When the first treatment operation S10 is performed, hydrogen radicals are transferred to the substrate W, and the temperature of the substrate W may be maintained at a first temperature (see FIG. 10). When the performance of the first treatment operation S10 is completed, the impurities I attached to the pattern P may be removed (see FIG. 11).

When the second treatment operation S20 is performed, hydrogen radicals are transferred to the substrate W, and the temperature of the substrate W may be maintained at a second temperature (see FIG. 12). When the performance of the second treatment operation S20 is completed, surface roughness of the substrate W may be improved (see FIG. 12).

In the exemplary embodiment, it is described that the substrate support unit 200 is the electrostatic chuck, but contrary to this, the substrate support unit may support the substrate by various methods. For example, the substrate support unit 200 may be provided as a vacuum chuck that adsorbs and maintains the substrate in vacuum.

The plasma including the hydrogen radicals may be direct plasma or remote plasma. The direct plasma may be directly generated within the treatment space 101, and the remote plasma is generated outside the treatment space 10 and is introduced into a reaction chamber. Contrary to this, the method of generating plasma including hydrogen radicals may be various, a radiofrequency (RF) plasma method, a microwave plasma method, an inductively coupled plasma method, a capacitively coupled plasma method, or an electron cyclotron resonance plasma method.

Further, in the foregoing example, the case where the plasma including hydrogen radicals is generated through microwaves has been described as an example, but the present invention is not limited thereto, and the foregoing exemplary embodiment may be identically or similarly applied to a device which includes a temperature adjusting member adjusting a temperature of the substrate and a plasma source generating plasma from process gas.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A method of treating a substrate, the method comprising:
a first treatment operation in which hydrogen radicals are transferred to a substrate of which a temperature is adjusted to a first temperature to treat the substrate; and
a second treatment operation in which the hydrogen radicals are transferred to the substrate of which the temperature is adjusted to a second temperature that is different from the first temperature to treat the substrate,
wherein a pattern having a pin structure is formed on the substrate and impurities containing germanium (Ge) is attached to the pattern,
wherein in the first treatment operation, the impurities are removed, and
wherein the second treatment operation is performed after the first treatment operation, and in the second treatment operation, surface roughness of the substrate that is made of a material containing silicon (Si) is improved.

2. The method of claim 1, wherein the second temperature is higher than the first temperature.

3. The method of claim 2, wherein the first temperature is 50° C. or higher and 300° C. or lower.

4. The method of claim 3, wherein the second temperature is 400° C. or higher and 700° C. or lower.

5. The method of claim 1, wherein a pressure within a vacuum chamber providing a space in which the substrate is treated is 10 mTorr or more and 4 Torr or less.

6. The method of claim 1, wherein plasma including the hydrogen radicals is any one of direct plasma and remote plasma.
